(19) United States
(12) Patent Application Publication
(10) Pub. No.: US 2018/0156436 A1
(43) Pub. Date: Jun. 7, 2018

(54) LEADFRAME, LUMINAIRE, GROUP OF LUMINAIRES AND METHOD FOR PRODUCING A LUMINAIRE

(71) Applicant: OSRAM GmbH, Munich (DE)

(72) Inventors: Thomas Rossmanith, Munich (DE); Friedrich Witzani, Munich (DE); Alexander Rampitsch, Ottobrunn (DE)

(21) Appl. No.: 15/830,058

(22) Filed: Dec. 4, 2017

(30) Foreign Application Priority Data
Dec. 5, 2016 (DE) 10 2016 224 170.2

(51) Int. Cl. F21V 23/06; H01L 23/495; H01L 33/62; F21V 31/04

(52) U.S. Cl. CPC F21V 23/06; H01L 23/49541; F21Y 2115/10; F21V 31/04; H01L 33/62

(57) ABSTRACT

In various embodiments, a leadframe is provided. The leadframe may include connection strips arranged alongside one another, said connection strips being connected via one or a plurality of holding webs. The connection strips have a contact section in each case at their first end section. At least in each case two adjacent connection strips form a strip group. Provision is made of at least one gap region in the region of second end sections of the connection strips of a respective strip group for contacting an electronic component.

### CROSS-REFERENCE TO RELATED APPLICATION

This application claims priority to German Patent Application Serial No. 10 2016 224 170.2, which was filed Dec. 5, 2016, and is incorporated herein by reference in its entirety.

### TECHNICAL FIELD

Various embodiments relate generally to a leadframe, e.g. for a luminaire. Furthermore, various embodiments relate to a luminaire, a group of luminaires and a method for producing a luminaire.

### BACKGROUND

The prior art discloses luminaires including a printed circuit board populated with a light emitting diode (LED) and with control electronics. The LED and the control electronics are connected to a plug via cables. The printed circuit board with the LED and the control electronics can be arranged in a transparent housing. In vehicle technology, for example, such a luminaire is used as ambient lighting for a vehicle door. Disadvantages of this solution include the high apparatus engineering complexity of the luminaire and the costly production.

### SUMMARY

In various embodiments, a leadframe is provided. The leadframe may include connection strips arranged alongside one another, said connection strips being connected via one or a plurality of holding webs. The connection strips have a contact section in each case at their first end section. At least in each case two adjacent connection strips form a strip group. Provision is made of at least one gap region in the region of second end sections of the connection strips of a respective strip group for contacting an electronic component.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a leadframe in accordance with one embodiment in a plan view;

FIGS. 2A and 2B show a luminaire in accordance with one embodiment in different production process in each case in a plan view; and

FIG. 3 shows a luminaire in accordance with a further embodiment in a plan view.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various embodiments provide a leadframe for a luminaire with which an apparatus engineering complexity for producing the luminaire is comparatively low. Furthermore, various embodiments provide a luminaire and a group of luminaires which can be produced with a low apparatus engineering complexity. Moreover, various embodiments provide a method for producing a luminaire with which the latter can be produced cost-effectively and simply in terms of apparatus engineering.

Various embodiments provide a leadframe or terminal frame, e.g. for a luminaire, which has connection strips arranged alongside one another, e.g. approximately at a parallel distance from one another. The connection strips can be connected via one or a plurality of holding webs. In various embodiments, the connection strips include a contact section in each case at their first end section, wherein the contact sections can be used for a plug for example in the finished product. In each case two or more adjacent connection strips can form a strip group or, with exactly two connection strips, a strip pair. In various embodiments, at least one gap region for contacting an electronic component is provided in the region of second end sections of the connection strips of a respective strip group. Said electronic component is for example a radiation source, such as a light emitting diode (LED), for example. In other words, the connection strips of a respective strip group are configured for contacting an electrical component, e.g. for contacting a radiation source, in each case at their second end section.

This solution may have the effect that with such a leadframe a luminaire can be produced extremely cost-effectively. This is made possible e.g. by virtue of the fact that provision is made of contact sections for a plug, connection strips for supplying power and regions for contacting or mounting at least one electronic component, which can then be supplied with power via the contact sections and the connection strips.

If a strip group includes more than two connection strips, such as three, for example, then it is conceivable for two connection strips to be used for operating a radiation source, such as e.g. an LED, and a third connection strip to be used for at least one further component, such as, for example, for a sensor, e.g. for a temperature sensor.

A conventional leadframe is a solderable metallic lead carrier in the form of a frame or comb for the mechanical production of electronic components.

A light emitting diode (LED) can be present in the form of at least one individually packaged LED or in the form of at least one LED chip including one or a plurality of light emitting diodes. A plurality of LED chips can be mounted on a common substrate (“submount”) and form an LED or be secured individually or jointly for example on a circuit board (e.g. FR4, metal-core circuit board, etc.) (“CoB”=Chip on Board). The at least one LED can be equipped with at least one dedicated and/or common optical unit for beam guiding, for example with at least one Fresnel lens or a collimator. Instead of or in addition to inorganic LEDs, for example on the basis of AlInGaN or InGaN or AlInGaP, generally organic LEDs (OLEDs, e.g. polymer OLEDs) can also be used. The LED chips can be directly emissive or include a phosphor mounted upstream. Alternatively, the light emitting component can be a laser diode or a laser diode arrangement. It is also conceivable to provide one OLED luminous layer or a plurality of OLED luminous layers or an OLED luminous region. The emission wavelengths of the light emitting components can be in the ultraviolet, visible or infrared spectral range. The light emitting components can additionally be equipped with a dedicated converter. In various embodiments, the LED chips emit white light in the standardized ECE white field from the automotive industry, for example realized by a blue emitter and a yellow/green converter.

In a further configuration, a center section can be formed between the first end sections and the second end sections of a respective strip group. In the finished product, said center section can then serve as a connection cable or as connection leads between a plug section, which includes the contact sections of a strip group, and a luminaire section, which includes the gap region, or a housing section, which includes the illuminant (LED) and the electronics for operating same.

In various embodiments, a gap region for contacting the electronic component can be provided in each case at one of the connection strips of a strip group.

In order that the contact sections can be used for a plug, for example, in the finished product simply in terms of apparatus engineering, said contact sections can be formed as contact pins. It is conceivable for the contact pins to be tin-plated or gold-plated.

If more than two connection strips, such as three, for example, are provided in the finished product, then the plug can also include a corresponding number of contact sections, such as three, for example, e.g. in the form of contact pins.

In various embodiments, in one or in a portion or in all of the connection strips or metal strips of a respective strip group, in particular in the center section, in each case at least one embossing or a plurality of embossings are introduced. It is thereby possible to increase a flexibility in this region. In other words, the connection strips, which can be used as cables or a cable replacement in the finished product, can be formed with a low mechanical stiffness by virtue of said connection strips being pre-embossed. In this case, the embossing is carried out for example in such a way that a material thickness is reduced and/or that the connection strips have an undulatory and/or a zigzag shape.

As a result of the embossing or the undulatory shape or as a result of the zigzag shape, it is furthermore possible to lengthen the connection strips in these regions by means of an axial tensile force. Consequently, the leadframe can easily be altered in terms of its size as necessary.

Alternatively or additionally, provision can be made for at least a portion of the connection strips or all of the connection strips of a strip group to have a or respectively a region having at least one reshaping section or reshaping sections deviating from the longitudinal direction of the connection strips. This can be provided for example in the case of the plug section and/or in the case of the luminaire section and/or in the case of the center section (if the latter is present). In the case of a tensile loading in the longitudinal direction of a connection strip having such a reshaping section, the reshaping section can be aligned into the longitudinal direction and be deformed, e.g. plastically. It is conceivable, for example, to configure such a reshaping section in an undulatory fashion and/or in a zigzag shape, as already explained above, and/or in some other nonlinear shape. In other words, a connection strip having such a section can be stretched like a “concertina” and thereby be plastically deformed as necessary, as a result of which a lengthening is made possible. This could also be achieved by the reshaping section being formed with a smaller thickness and/or with at least one notch. In the case of a tensile loading, the connection strip is then deformed, e.g. plastically, in this region.

It is furthermore conceivable to deform at least one portion of the connection strips or all of the connection strips of a strip group plastically in a torsion section about the longitudinal axis thereof. Consequently, a connection strip having a torsion section can be divided into two portions. The first portion is then oriented differently than the second portion. By way of example, the second portion is rotated by approximately 90° with respect to the first portion, as viewed about the longitudinal axis. An increased flexibility is achieved as a result. In various embodiments, the torsion section is formed in the center section, if the latter is provided.

Alternatively or additionally, it is conceivable for one or a plurality of bends to be introduced in a connection strip or in a portion or in all of the connection strips of a respective strip group, in order to increase a mechanical stiffness. In various embodiments, the leadframe includes or essentially consists of an electrically conductive material, for example copper (Cu), such as is also used in LED production. The leadframe may be zinc-plated.

In a further configuration, one of the connection strips or a portion of the connection strips or a respective connection strip of a strip group may include at least one terminal or one terminal piece. In other words, one terminal or a plurality of terminals can also be shaped alongside the contact sections in the leadframe. This makes it possible for example to connect a plurality of strip groups in series with one another and/or to connect or to mount at least one further electrical component. In various embodiments, the terminals are formed in the region of the plug section or in the region of the luminaire section or in the region of the center section. A terminal can be embodied for example as a soldering area for receiving terminals of electronic components.

In various embodiments, the connection strips of a strip group are connected to a contacting section approximately in the region of their second end section in order to form a closed electrical circuit in the finished product in a simple manner in terms of apparatus engineering. The connection strips can thus be electrically and mechanically connected via the contacting section.

An, e.g. elongate, bridge strip can be arranged in the gap region, which is e.g. formed at one of the connection strips. Said bridge strip can then be secured via a holding web on an adjacent connection strip, e.g. if the strip group includes two connection strips. End sections of the bridge strip may be spaced apart from the connection strip into whose gap region the bridge strip is inserted. It is thereby possible to create a contacting region for a first electrical component, e.g. for the radiation source, and a further contacting region for a second electrical component, e.g. control electronics.

In various embodiments, the bridge strip is secured via a holding web on the adjacent connection strip of the adjacent strip group. It is furthermore conceivable to arrange the bridge strip simply in line with the connection strip into whose gap region the bridge strip is inserted. In various embodiments, every second connection strip of the leadframe includes a gap region, e.g. if the strip group includes two connection strips. The gap region can be formed approximately adjacent to the contacting section.

In various embodiments, provision can be made of a gap region at an end section of a connection strip of a respective strip group, and a further gap region between both end sections of the connection strips of a strip group, e.g. if the strip group includes two connection strips. One gap region can then be bridged with a first electronic component, such as control electronics, for example. The other gap region, e.g. the gap region between the two end sections, can be bridged with a further electronic component, e.g. with the radiation source.

In various embodiments, in each case at least one holding web is formed between the connection strips. Alternatively or additionally, provision can be made for a common holding web to be formed, which extends for example approximately transversely with respect to the connection strips. The common holding web is preferably connected to the first end sections of the connection strips, whereby a comblike leadframe can be formed. It is also conceivable for the common holding web to include connection strips on both of its longitudinal sides. During the production of products, e.g. luminaires, from the leadframe, the holding webs can then be severed and/or separated. The severing or separation is carried out cost-effectively and in a simple manner e.g. mechanically, e.g. by means of a stamping apparatus.

In various embodiments, provision can be made for the second end section of a connection strip of a respective strip group or the second end section of a respective connection strip of a respective strip group to have a widened wall section or widened plate section, which serves e.g. as a diaphragm. The wall section or the wall sections can thus be provided in a simple manner in terms of apparatus engineering in order then to shade stray light for example during the use of a luminaire. The wall section or one of the wall sections or both wall sections of the strip group can serve as part of an electrical circuit for the power supply of the electrical component in a simple manner in terms of apparatus engineering. Alternatively or additionally, provision can be made for the wall section or one of the wall sections or both wall sections of the strip group to be grounded and/or isolated from the electrical circuit for the power supply of the electrical component. The wall section and/or the wall sections can also be altered with regard to a position and/or a configuration by bending, e.g. in the production process.

Various embodiments provide a luminaire or a group of luminaires formed from a leadframe, e.g. as per one or more of the preceding aspects. In a simple manner in terms of apparatus engineering, the luminaire includes at least two, e.g. thin, connection strips or metal strips arranged approximately alongside one another, e.g. at a parallel distance. Said strips can have a contact section in each case at their first end section. In the region of their second end sections the connection strips can have a gap region equipped with a radiation source, in particular an LED. In a simple manner in terms of apparatus engineering, the contact sections can form a plug section. The second end sections can then be provided for a luminaire section.

This solution may have the effect that the luminaire is configured extremely simply in terms of apparatus engineering and cost-effectively in comparison with the prior art. With the luminaire according to various embodiments, a number of components is extremely small. Furthermore, such a luminaire can be manufactured with low production complexity, e.g. with a small number of production processes.

In various embodiments, a center section may be provided between the contact section and the luminaire section, said center section serving as an, e.g. flexible, connection cable or connection lead between the plug section and the luminaire section in a simple manner in terms of apparatus engineering.

In various embodiments, the connection strips include a further gap region in the region of their second end sections, said further gap region being equipped with electronics, e.g. with control electronics. In this case, the gap region may be part of the luminaire section.

In a further configuration, the plug section can be enclosed, e.g. encapsulated by injection molding, at least in sections or substantially completely or completely by a plug housing in a simple manner. As a result, the plug section can be used as a plug with low apparatus engineering complexity. In this case, the encapsulation by injection molding is carried out e.g. in an injection molding method or plastic injection molding method. It is thus conceivable, for example, for the plug housing to be formed cost-effectively from a plastic. The latter can be transparent, for example.

In various embodiments, the luminaire section is enclosed, e.g. encapsulated by injection molding, at least in sections or substantially completely or completely by a lamp housing. This can likewise be carried out by an injection molding method or plastic injection molding method. The lamp housing can thus be formed for example from plastic, wherein a transparent plastic can be used here as well.

The encapsulation of the luminaire section by injection molding can be carried out in such a way that the LED is free or the lamp housing is open toward the outside in the region of the LED. In this case, it is conceivable for the open region to be able to be covered by a housing cover. It is furthermore conceivable for the housing cover to be injection molded concomitantly, e.g. in the same injection molding process, with a hinge, e.g. via a film hinge. After the removal of the luminaire section encapsulated by injection molding, the housing cover connected via the hinge can be brought to its closed position. Alternatively, if a separate housing cover is provided, the housing cover can be connected to the housing in order to cover the LED. This is carried out for example by means of a positively locking connection, e.g. by means of a snap-action connection.

It is conceivable for a material for the plug housing and the lamp housing to be identical in a cost-effective manner.

Furthermore, it is conceivable, particularly if no center section is provided, for the plug section and the luminaire section to be provided in a common housing, which may be created by encapsulation by injection molding.

If a group of luminaires are provided, then the individual luminaires can be connected to one another in a simple manner via the lamp housing and/or the plug housing and/or via the common housing and/or via the web. This solution may have the effect that a linear luminaire can be formed in a simple manner in terms of apparatus engineering. Given corresponding arrangement and configuration of the leadframe, a matrix-shaped luminaire may also be able to be formed. The luminaire can then serve as “goods sold by the meter”, as a result of which an arbitrary separation of the group, e.g. by cutting, is made possible during use. The connection between two luminaires or respectively two luminaires can be carried out in a simple manner via one or a plurality of connection webs. The latter can be concomitantly produced e.g. in the injection molding method. In a further configuration of the invention, it is conceivable for at least one web to engage around the center section, e.g. at least in sections or substantially completely or completely, in order to position the connection strips with respect to one another. In this case, the web may be connected to both connection strips. The web is partly or completely injection-molded around the center section, for example, as a result of which it is produced e.g. by means of an injection molding method or plastic injection molding method. The complete encapsulation by injection molding may have the further effect that a complete insulation of the center section can be effected. By way of example, the web can then approximately bear against the lamp housing and/or plug housing if these are provided. If complete encapsulation by injection molding is not present, the web can extend approximately transversely with respect to the connection strip. If two or more webs are provided, then they can be arranged for example at a parallel distance from one another. By way of example, a plastic can be used as material for the web. This can be a transparent plastic. In order to save costs, it is conceivable for the material of the web to correspond to the material of the plug housing and/or of the lamp housing. Alternatively or additionally, provision can be made for choosing a material or a plastic for the web which is softer in comparison with the material for the plug housing and/or for the lamp housing. A flexibility of the web is thus increased.

It is conceivable to use as material for the plug housing and/or the lamp housing or the common housing polymethyl methacrylate (PMMA) as material. For the web, particularly if a high flexibility is desired, silicone can be used as material.

In various embodiments, it is conceivable to form in the lamp housing or in the common housing at least one diaphragm as an alternative or in addition to the wall section or wall sections. The at least one diaphragm is provided for example as an additional component which is concomitantly produced by encapsulation by injection molding or is secured on the lamp housing or on the common housing. It is also conceivable to provide the housing or the lamp housing with an additional layer, which acts as a diaphragm. It is furthermore conceivable for the diaphragm to be formed by a light-nontransmissive plastic in the injection molding method. In various embodiments, the diaphragm may include or essentially consist of an electrically insulating material.

Various embodiments provide a method for producing a luminaire or a group of luminaires, e.g. in accordance with one or more of the preceding aspects, from a leadframe in accordance with one or more of the preceding aspects, including the following processes:
equipping the connection strips of a strip group with one or a plurality of electronic components, e.g. with a radiation source and/or with control electronics;
encapsulating the plug section and/or the luminaire section with a plastic, e.g. with a transparent plastic, by injection molding in order to form a plug housing and/or a lamp housing in a plastic injection molding method.

This solution may have the effect that a luminaire can be produced with low production complexity.

In the process of encapsulating the plug section and/or the luminaire section by injection molding or after the process of encapsulating the plug section and/or the luminaire section by injection molding, provision can be made for encapsulating the center section, if present, by injection molding in a plastic injection molding method in order to form a web. A flexible plastic may be used in this case. In other words, leadframe strips serving as connection wires can thereby be encapsulated with a flexible plastic by injection molding.

For encapsulation by injection molding, the leadframe may be introduced into an injection mold and correspondingly encapsulated by injection molding. If a possible center section is intended to be encapsulated by injection molding for example with a different plastic, then a so-called “two-component encapsulation by injection molding” could be carried out. In this case, e.g. firstly, the housing of the plug section and/or luminaire section or the common housing is produced by encapsulation by injection molding with a first plastic, and afterward or simultaneously the center section is encapsulated by injection molding with a different plastic.

In various embodiments, in the method according to various embodiments, provision is made for the holding web or holding webs to be severed, e.g. after the encapsulation by injection molding. It is furthermore conceivable to shorten the holding webs or the holding web after severing.

During the production of the group of luminaires, the connection webs for connecting the luminaires may be formed in the plastic injection molding method.

If the connection strips have one or a plurality of sections deviating from a longitudinal direction, such as e.g. a zigzag shape, then these can be elongated and in particular plastically deformed in a method process. This is carried out for example before the encapsulation by injection molding. Furthermore, this lengthening may be carried out before or after the equipping process.

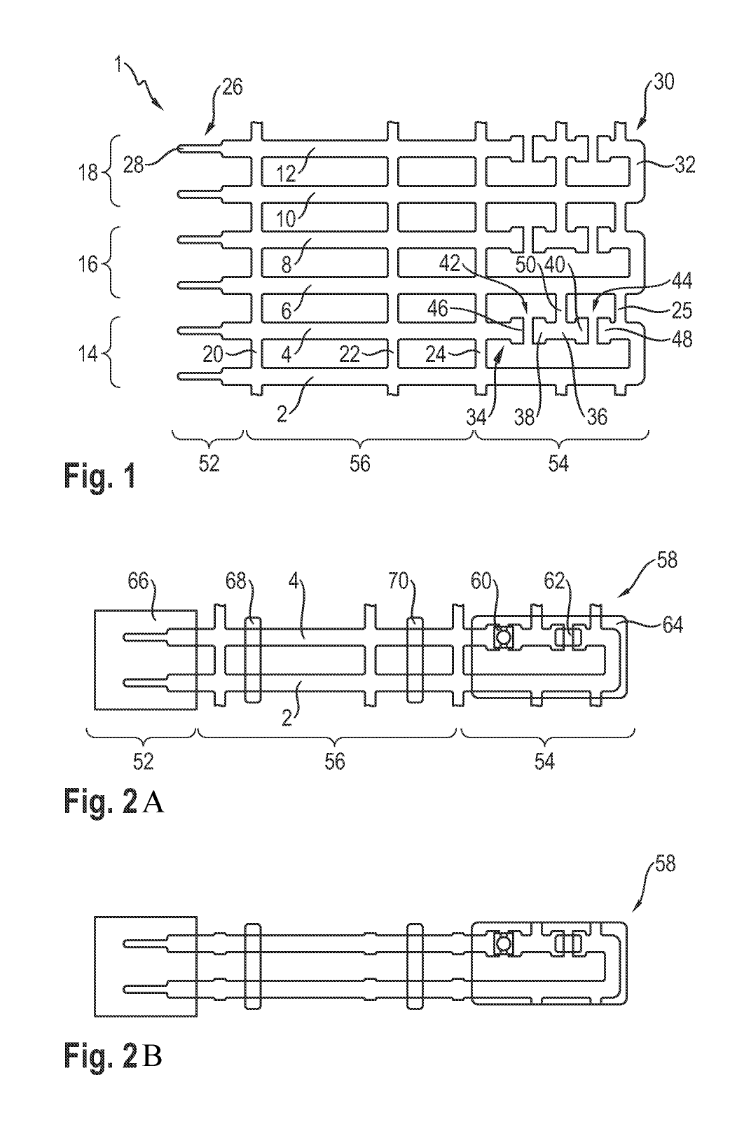

A leadframe 1 is illustrated in accordance with FIG. 1. Said leadframe serves for the simple production of a luminaire. The leadframe 1 includes a multiplicity of, in particular thin, connection strips 2 to 12 arranged approximately at a parallel distance. In each case two adjacent connection strips 2 to 12 here form a strip group 14, 16 and 18 or a strip pair. The connection strips 2 to 12 are connected to one another in each case via holding webs 20, 22, 24 and 25, which are thus formed in each case between two connection strips 2 to 12. For the sake of simplicity, only four holding webs 20 to 24 and 25 are provided with a reference sign in accordance with FIG. 1. The holding webs 20, 22, 24 and 25 extend approximately transversely with respect to the connection strips 2 to 12 and are arranged approximately at a parallel distance with respect to one another. A respective strip group 14 to 18 is used for producing a luminaire.

At their first end section 26, the connection strips 2 to 12 include in each case a contact section in the form of a contact pin 28, which forms part of a plug in a finished produced luminaire. Furthermore, the connection strips 2 to 12 of a respective strip group 14 to 18 are connected to a contacting section 32 via their respective second end section 30. The connection strips 2 to 12 of a respective strip group 14 to 18 are then configured approximately in a U-shaped fashion. Furthermore, a connection strip 4, 8, 12 of a respective strip group 14 to 18 includes a gap region 34. The latter is formed approximately adjacent to the contacting section 32. A bridge strip 36 is arranged into a respective gap region 34 approximately parallel to the respective connection strip 4, 8, 12. In this case, the bridge strip 36, with its end sections 38 and 40, is spaced apart from the respective connection strip 4, 8 and 12, as a result of which a first contacting region 42 is formed for a radiation source, e.g. for a light emitting diode (LED), and a second contacting region 44 is formed for a further electronic component, e.g. in the form of control electronics. In this case, the end sections 38 and 40 are arranged respectively opposite a contact region 46, 48 of the respective connection strip 4, 8, 12. The contact regions 46, 48 and the end sections 38, 40 are formed in a widened fashion in comparison with the rest of the connection strip 4, 8, 12 in order to enable an improved contacting with the corresponding electronic components. A respective bridge strip 36 is furthermore secured via a holding web 50 on the respectively adjacent connection strip 6, 10 of the respectively adjacent strip group 16, 18. Consequently, in the case of the leadframe 1 provision is made alternately of a connection strip 2, 6, 10 having a holding web 50 and a bridge strip 36 and a connection strip 4, 8, 12 having a gap region 34.

The strip groups 14 to 18 can be divided into three regions. In this case, the first end sections 26 having the contact pins 28 form a plug section 52. The further end sections 30 having the contacting section 32, the gap region 34 and the bridge strip 36 then form a luminaire section 54. A center section 56 is formed between the plug section 52 and the luminaire section 54.

Production of a luminaire 58 is explained in accordance with FIG. 2a and FIG. 2b, said luminaire being produced from the leadframe 1 from FIG. 1. In this case, the production of the luminaire 58 is explained by way of example on the basis of the strip group 14 having the connection strips 2, 4 from FIG. 1. In order to produce the luminaire 58, firstly the strip groups 14 to 18, see FIG. 1, are equipped with an LED 60 and control electronics 62 in accordance with FIG. 2a. Afterward, both the luminaire section 54 and the plug section 52 are encapsulated with a transparent plastic by injection molding in a plastic injection molding method. As a result, a lamp housing 64 is formed in the luminaire section 54. A plug housing 66 is then formed in the case of the plug section 52. The housings 64 and 66 can be fashioned approximately at the same time in this case. Likewise at the same time or in a subsequent step, in the case of the center section 56 webs 68, 70 can be formed by the connection strips 2, 4; 6, 8 and 10, 12 of a respective strip group 14 to 18 being encapsulated by injection molding; see also FIG. 1. In this case, the webs 68, 70 are arranged approximately at a parallel distance from one another and extend approximately transversely with respect to the connection strips 2, 4. As an alternative to forming the webs 68 and 70, it would be conceivable for the connection strips 2, 4 in the region of the center section 56 likewise to be completely encapsulated with plastic by injection molding. In various embodiments, a comparatively flexible plastic is then involved since the center region 56 performs the function of connection cables between the plug housing 66 and the lamp housing 64.

In accordance with FIG. 2b, in a subsequent process, the holding webs 20, 22, 24, 25 and 50 for a respective strip group 14 to 18, see also FIG. 1, are separated and shortened as necessary.

It is conceivable for a multiplicity or plurality of luminaires 58 to be produced simultaneously from the leadframe 1.

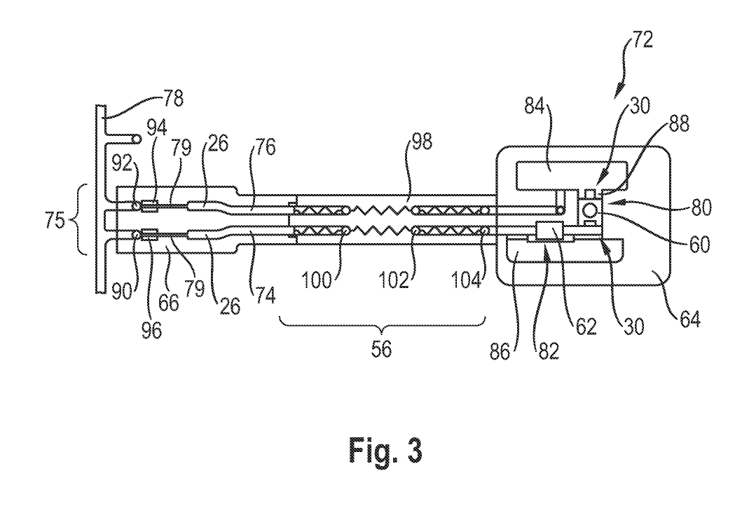

FIG. 3 shows a luminaire 72 in a further embodiment. In contrast to the previous embodiment in accordance with FIG. 1 to FIG. 2b, connection strips 74, 76, two of which are illustrated as a strip group 75 or as a strip pair, by way of example in accordance with FIG. 3, are arranged by their first end section 26 on a common holding web 78. A respective end section 26 forms a contact section in the form of a contact pin 79. The connection strips 74 and 76 are thus secured in a comblike manner on the holding web 78.

Furthermore, the connection strips 74, 76, at their second end sections 30, do not include a contacting section as in FIG. 1 but rather a gap region 80 equipped with the LED 60. The connection strip 74 includes a further gap region 82 adjacent to the gap region 80, said further gap region being equipped with the control electronics 62.

Furthermore, in accordance with FIG. 3, a wall section 84 and 86 is formed at a respective connection strip 74 and 76 in the region of the second end section 30 thereof. In this case, the wall section 84 of the connection strip 76 is part of an electrical circuit. It is configured in a plate-shaped and elongate fashion and extends approximately at a parallel distance from the rest of the connection strip 76. Via its inner side, it is connected firstly to the rest of the connection strip 76 and secondly to a contact region 88 for contacting the LED 60. The other wall section 86 is arranged approximately parallel to the gap region 82, and is connected to the connection strip 74 before and after the gap region 82. In this case, the wall section 86 is electrically insulated from the rest of the connection strip 74, by virtue of said wall section being separated from the connection strip 74 after the production of the lamp housing 64, for example, or by virtue of an electrically insulating material being provided between the wall section 86 and the rest of the connection strip 74. The wall section 86 is likewise configured approximately in a plate-shaped and elongate fashion and extends approximately at a parallel distance from the wall section 84. The electrical insulation of the wall section 86 may have the effect that requirements in respect of electromagnetic compatibility (EMC) can thereby be implemented. Furthermore, it is conceivable for the wall section to be grounded.

In accordance with FIG. 3, provision is furthermore made for the center section 56 to be completely encapsulated by a flexible plastic by injection molding. By contrast, the plastic for the lamp housing 64 and the plug housing 66 may include or essentially consist of a comparatively hard plastic.

The plug housing 66 includes two stamped holes 90 and 92, via which the first end sections 26 can be separated from the holding web 78.

In accordance with FIG. 3, holding regions 94 and 96 can furthermore be provided in the case of the plug housing 66.

Furthermore, in accordance with FIG. 3, in the case of the center section 56 with the web 98 fully encapsulated by injection molding, provision is made for providing holding points 100, 102 and 104 for a respective connection strip 74 and 76. Said holding points can be formed by virtue of holding pins in the injection mold engaging on the connection strips 74 and 76 for holding purposes.

In FIG. 3, provision is furthermore made for the connection strips 74, 76 to be embossed in the region of the center section 56 in order to reduce a mechanical stiffness in said region. In accordance with FIG. 3, a zigzag configuration of the center section 56 is additionally implemented.

A luminaire produced from a leadframe is disclosed. In this case, contact sections and a luminaire section are formed from the leadframe. Provision can be made for the contact sections and the luminaire section to be connected via a center section of the leadframe, which serves as a connection cable.

### LIST OF REFERENCE SIGNS

Leadframe 1

Connection strip 2 to 12

Strip group 14 to 18

Holding web 20 to 24, 25

First end section 26

Contact pin 28

Second end section 30

Contacting section 32

Gap region 34

Bridge strip 36

End section 38, 40

Contacting region 42, 44

Contact region 46, 48

Holding web 50

Plug section 52

Luminaire section 54

Center section 56

Luminaire 58

LED 60

Control electronics 62

Lamp housing 64

Plug housing 66

Webs 68, 70

Luminaire 72

Connection strips 74, 76

Strip group 75

Holding web 78

Contact pin 79

Gap region 80, 82

Wall section 84, 86

Contact region 88

Stamped hole 90, 92

Holding region 94, 96

Web 98

Holding point 100, 102, 104

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A leadframe, comprising:
connection strips arranged alongside one another, said connection strips being connected via one or a plurality of holding webs;
wherein the connection strips have a contact section in each case at their first end section;
wherein at least in each case two adjacent connection strips form a strip group; and
wherein provision is made of at least one gap region in the region of second end sections of the connection strips of a respective strip group for contacting an electronic component.

2. The leadframe of claim 1,
wherein a center section is formed between the first end sections and the second end sections of a respective strip group, said center section serving as a connection lead between a plug section, which comprises the contact sections of a strip group, and a luminaire section, which comprises the at least one gap region.

3. The leadframe of claim 1,
wherein a respective contact section is formed as a contact pin.

4. The leadframe of claim 2,
wherein in one or in both connection strips of a respective strip group in the center section in each case at least one embossing or a plurality of embossings are introduced.

5. A luminaire formed from a leadframe, comprising:
at least two connection strips arranged approximately alongside one another, said connection strips having a contact section in each case at their first end section and having at their second end sections a gap region equipped at least with a radiation source;
wherein the contact sections form a plug section, and wherein the second end sections form a luminaire section.

6. The luminaire of claim 5,
wherein a center section is provided between the plug section and the luminaire section, said center section serving as a connection cable between the plug section and the luminaire section.

7. The luminaire of claim 5,
wherein the connection strips are equipped with electronics alongside the radiation source via the gap region or via further gap regions.

8. The luminaire of claim 5,
wherein the plug section is enclosed by a plug housing.

9. The luminaire of claim 8,
wherein the plug section is encapsulated by injection molding by a plug housing.

10. The luminaire of claim 5,
wherein the luminaire section is enclosed by a lamp housing.

11. The luminaire of claim 10,
wherein the luminaire section is encapsulated by injection molding by a lamp housing.

12. The luminaire of claim 5,
wherein the plug section and the luminaire section are enclosed by a common housing.

13. The luminaire of claim 12,
wherein the plug section and the luminaire section are encapsulated by injection molding by a common housing.

14. The luminaire of claim 6,
wherein the center section is enclosed by a web.

15. The luminaire of claim 14,
wherein the center section is encapsulated by injection molding by a web.

16. A group of luminaires, comprising:
each luminaire of the group of luminaires comprising:
at least two connection strips arranged approximately alongside one another, said connection strips having a contact section in each case at their first end section and having at their second end sections a gap region equipped at least with a radiation source;
wherein the contact sections form a plug section, and wherein the second end sections form a luminaire section;
wherein the luminaires are connected to one another via connection webs.

17. A method of manufacturing a luminaire from a leadframe,
the leadframe comprising:
connection strips arranged alongside one another, said connection strips being connected via one or a plurality of holding webs;
wherein the connection strips have a contact section in each case at their first end section;
wherein at least in each case two adjacent connection strips form a strip group; and
wherein provision is made of at least one gap region in the region of second end sections of the connection strips of a respective strip group for contacting an electronic component;
the method comprising:
equipping the connection strips of a strip group with one or a plurality of electronic components;
encapsulating at least one of the plug section or the luminaire section with a plastic by injection molding in order to form at least one of a plug housing or a lamp housing or a common housing in a plastic injection molding method.

18. The method of claim 17, further comprising:
encapsulating the center section with a plastic by injection molding in order to form a web in a plastic injection molding method.

19. The method of claim 17,
wherein severing of the holding web or holding webs is carried out by injection molding.

20. The group of luminaires of claim 16,
wherein the group of luminaires are connected to one another via connection webs produced in the plastic injection molding method.
